(19) United States
(12) Patent Application Publication
(10) Pub. No.: US 2015/0068577 A1
(43) Pub. Date: Mar. 12, 2015

(54) SOLAR PANEL

(71) Applicant: AU Optronics Corporation, Hsin-Chu (TW)

(72) Inventors: Kuan-Chou HOU, HSIN-CHU (TW); Chun-Ming YANG, HSIN-CHU (TW)

(73) Assignee: AU Optronics Corporation, Hsin-Chu (TW)

(21) Appl. No.: 14/197,420

(22) Filed: Mar. 5, 2014

(30) Foreign Application Priority Data
Sep. 6, 2013 (CN) 201310403916.7

(51) Int. Cl. H01L 31/042

(52) U.S. Cl. CPC H01L 31/042
USPC 136/244

(57) ABSTRACT

A solar panel includes a substrate, plural solar cells, wires, and plural bypass diodes. The substrate includes a bottom area, a middle area, and a top area vertically arranged from bottom to top. The middle area includes a first zone, a second zone and a third zone horizontally arranged from left to right. The solar cells are disposed on the substrate in columns and in rows. The bottom area includes at least two rows of the solar cells. The top area includes at least two rows of the solar cells. The wires serially connect the solar cells. The bypass diodes are disposed on the substrate, in which each of the first zone, the second zone, the third zone, the bottom area and the top area is disposed with at least one of the bypass diodes.

### RELATED APPLICATIONS

This application claims priority to Chinese Application Serial Number 201310403916.7, filed Sep. 6, 2013, which is herein incorporated by reference.

### BACKGROUND

1. Field of Invention

The present invention relates to a solar panel.

2. Description of Related Art

Solar panel modules use the photovoltaic effect to generate voltage or electric current while exposed to sunlight. In recent years, due to the promotion of renewable energy by many countries, the solar panel module industry has been growing very fast.

Solar panel modules can generate current or voltage outdoors, and can also be applied to indoor electrical products. When the solar panel module is applied to indoor electrical products, safety requirements are high, even though indoor environments are not as harsh as outdoor environments. During use of the solar panel module, the most common safety issue is that related to the generation of areas of extremely high temperature (or “hot spots”).

There are many causes for the generation of hot spots. For instance, a hot spot may be generated on a solar panel module due to a defect in the solar panel module, non-uniform welding, partial shading of the solar panel module, and a difference between solar cells in the solar panel module. Among these different causes of hot spots, “partial shading” is the most difficult to avoid and control. During use of a solar panel module, if a portion of the solar cells is shaded, a high resistance will be generated in the circuitry around such a portion of the solar cells, resulting in an abrupt increase in the temperature of this shaded area.

### SUMMARY

A solar panel of the present invention is provided to minimize a reduction in efficiency related to generating electric power caused by partial shading of the solar panel.

According to one embodiment of the present invention, the solar panel includes a substrate, a plurality of solar cells, a plurality conductive wires and a plurality bypass diodes. The substrate includes a bottom area, a middle area, and a top area vertically and sequentially implemented from bottom to top. The middle area includes a first zone, a second zone and a third zone horizontally and sequentially implemented from left to right. The solar cells are disposed on the substrate in columns and in rows. The bottom area includes at least two rows of the solar cells, and the top area includes at least two rows of the solar cells. The wires serially connect the solar cells. The bypass diodes are disposed on the substrate, in which each of the first zone, the second zone, the third zone, the bottom area and the top area is disposed with at least one of the bypass diodes.

According to one embodiment of the present invention, the solar panel includes a substrate, a plurality of solar cells, a plurality conductive wires and a plurality bypass diodes. The substrate includes a bottom area, a middle area, and a top area vertically arranged from bottom to top. The top area includes a first zone, a second zone and a third zone horizontally arranged from left to right. The solar cells are disposed on the substrate in columns and in rows. The bottom area includes at least two rows of the solar cells. The wires serially connect the solar cells. The bypass diodes are disposed on the substrate, in which each of the first zone, the second zone, and the third zone is disposed with at least one of the bypass diodes, and the bottom area is disposed with at least one of the bypass diodes.

According to one embodiment of the present invention, the solar cells of the solar panel can be divided into a plurality of areas or zones, and each of areas or zones is disposed with a bypass diode to meet different environmental conditions. Hence, a suitable solar panel configuration may be realized to keep power generation loss to a minimum due to partial shading on the solar panel.

It is to be understood that both the foregoing general description and the following detailed description are given by way of example, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1-4 are schematic diagrams of a solar panel according to embodiments of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

To overcome the problem of hot spots caused by partial shading of solar cells, more bypass diodes are implemented in a solar panel and connected to solar cells thereof in parallel. However, the solar panel module may encounter different environments, seasonal changes, tree growth in the area surrounding the solar panel module, and other such external factors, such that the areas of partial shading will be different for each solar panel module. Thus, there is a need carefully and flexibly consider the location of the bypass diodes and the number thereof that are connected to the solar cells in parallel so as to prevent the solar panel module from undesirable power generation waste.

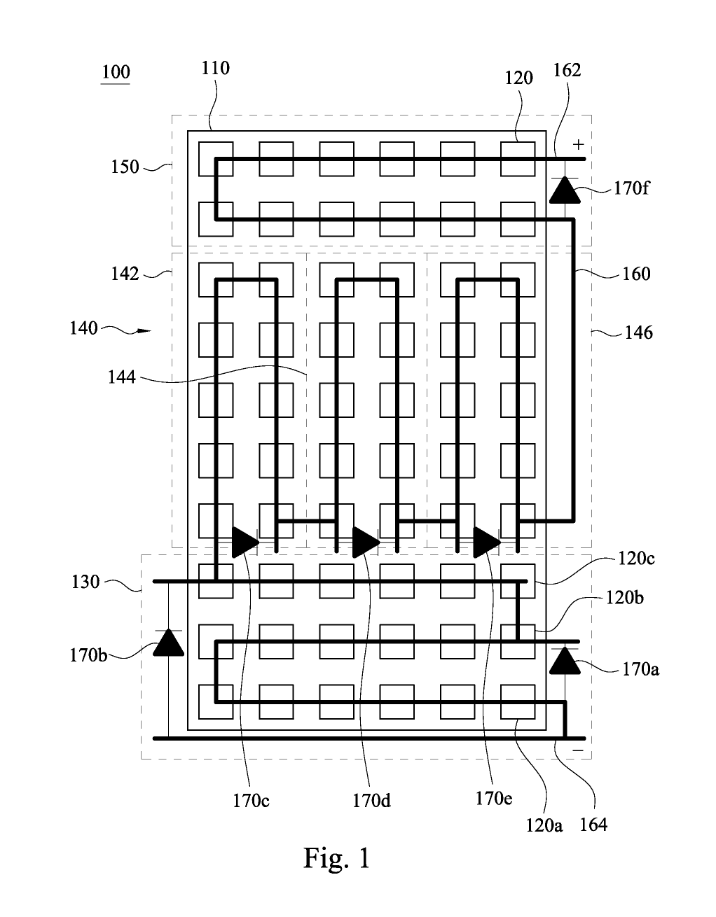

FIG. 1 is a schematic diagram of a solar panel according to a first embodiment of the present invention. The solar panel 100 includes a substrate 110 and a plurality of solar cells 120 disposed on the substrate 110. The solar cells 120 are disposed in rows and columns. According to the first embodiment of the present invention, the solar cells 120 are disposed on the substrate 110 in a 10×6 matrix. The solar cells 120 of the first embodiment are formed in the shape of squares. In other embodiments, the solar cells 120 may be formed in the shape of rectangles, or circles, or other polygon shapes.

The substrate 110 includes a bottom area 130, a central area 140, and a top area 150 that are vertically and sequentially disposed from bottom to top. The bottom area 130 includes at least two rows of the solar cells 120, and the top area 150 includes at least two rows of the solar cells 120. The central area 140 is disposed between the bottom area 130 and the top area 150.

According to the first embodiment, for example, the bottom area 130 includes three rows of the solar cells 120, the central area 140 includes five rows of the solar cells 120, and the top area 150 includes two rows of the solar cells 120. Each row includes six solar cells 120.

The central area 140 has a first zone 142, a second zone 144, and a third zone 146 that are horizontally and sequentially disposed from left to right. Specifically, the first zone 142 is located at the left side of the central area 140, the third zone 146 is located at the right side of the central area 140, and the second zone 144 is located between the first zone 142 and the third zone 146.

The solar panel 100 further includes a plurality of conducting wires 160, and the solar cells 120 are serially connected through the conducting wires 160. Wherein the conducting wires 160 is connected with the electrode of each of solar cell 120. It is to be noted that the conducting wires 160 of FIG. 1 are used to represent the electrical connectivity among the solar cells 120, and their illustration is not meant to limit the number of conducting wires or solders among the solar cells 120. The solar panel 100 includes a first terminal 162 and a second terminal 164 that have opposite polarities. According to the first embodiment, the first terminal 162 is a positive electrode (or namely positive polarity end), and the second terminal 164 is a negative electrode (or namely negative polarity end). The first terminal 162 and the second terminal 164 are used to connect to external circuits or electrically connect to another solar panel. The first terminal 162 and the second terminal 164 are disposed on the same side of the substrate 110. Specifically, the first terminal 162 and the second terminal 164 of the conducting wires 160 are disposed on the same side of the substrate 110, and the first terminal 162 is connected to the first solar cell 120 in the top area 150, while the second terminal 164 is connected to the last solar cell 120 of the bottom area 130. The conducting wires 160 sequentially and serially connect the solar cells 120 in the top area 150, then sequentially and serially connect the solar cells 120 in the third zone 146, the second zone 144, and the first area 142, and finally sequentially and serially connect the solar cells 120 in the bottom area 130.

The solar panel 100 further includes a plurality of bypass diodes 170a-170f. The bypass diodes 170a and 170b are connected in parallel to the solar cells 120 of the bottom area 130. Specifically, the bottom area 130 includes a first row of the solar cells 120a, a second row of the solar cells 120b, and a third row of the solar cells 120c that are sequentially arranged. The bypass diode 170a is connected to the first row of the solar cells 120a and the second row of the solar cells 120b, and the bypass diode 170b is connected to the first row of the solar cells 120a and the third row of the solar cells 120c. The bottom area 130 includes the bypass diodes 170a and 170b to prevent the generation of hot spots occurring due to partial shading of the solar panel 100. For instance, if the first row of the solar cells 120a is shaded, the second row of the solar cells 120b is shaded, or the first row of the solar cells 120a and the second row of the solar cells 120b are both shaded at the same time, then the first row of the solar cells 120a and the second row of the solar cells 120b will be bypassed by the bypass diode 170a, and the third row of the solar cells 120c will continue to function normally. If the solar cells 120a, 120b, 120c in the first, second, and third rows are all shaded at the same time, then the first row of the solar cells 120a, the second row of the solar cells 120b, and the third row of the solar cells 120c are bypassed by the bypass diode 170b. Thus, such a technique can deal with the problem of partial shading of the solar panel 100.

The bypass diode 170c is connected in parallel to two columns of the solar cells 120 of the first zone 142 that are serially connected. The bypass diode 170d is connected in parallel to two columns of the solar cells 120 of the second zone 144 that are serially connected. The bypass diode 170e is connected in parallel to two columns of the solar cells 120 of the third zone 146 that are serially connected. Each of the bypass diodes 170c-170e of the central area 140 is connected to two adjacent columns of the solar cells 120. The bypass diode 170f of the top area 150 is connected to two adjacent rows of the solar cells 120, preferred, the bypass diode 170f of the top area 150 is connected to two immediately adjacent rows of the solar cells 120. It is to be noted that in practice, the bypass diodes 170a-170f are all disposed on the substrate 110. However, in FIG. 1, the bypass diodes 170a, 170b, and 170f are shown positioned outside of the substrate 110 so as to enable a clear depiction of the connections thereof with elements of the solar panel 100. The drawings related to the subsequent embodiments will also be presented in the same way, and a similar explanation will not be repeated.

In other words, the solar panel 100 includes a bottom area solar cell string in the bottom area 130, a top area solar cell string in the top area 150, a first central area solar cell string in the first zone 142, a second central area solar cell string in the second zone 144, and a third central area solar cell string in the third zone 146. The bottom area solar cell string, the top area solar cell string, the first central area solar cell string, the second central area solar cell string, and the third central area solar cell string are connected in series. The first central area solar cell string, the second central area solar cell string, and the third central area solar cell string are connected in series and disposed between the bottom area solar cell string and the top area solar cell string. The second central area solar cell string is located between the first central area solar cell string and the third central area solar cell string. Each of the bottom area solar cell string, the top area solar cell string, the first central area solar cell string, the second central area solar cell string, and the third central area solar cell string includes a plurality of the solar cells 120 connected to each other in series. Some of the solar cells 120 of the bottom area solar cell string, the top area solar cell string, the first central area solar cell string, the second central area solar cell string, and the third central area solar cell string are connected to at least one bypass diode in parallel. If some of the solar cells 120 are shaded, then only the solar cell string of the solar cells 120 that are shaded will be bypassed, and other solar cells 120 that are not shaded will still normally function.

The substrate 110 may be made of glass, plastic or their combination. For instance, the substrate 110 may be made of tempered glass, polyvinyl fluoride (PVF, Tedlar® of DuPont), polyethylene terephthalate (PET), Polyethylene Naphthalate (PEN) or their combination. It is to be understood that such materials are given by way of example and do not limit the present invention. Persons having ordinary skill in the art may flexibly choose the material of the substrate 110 depending on actual requirements.

The solar cells 120 has p-n semiconductor material or p-i-n semiconductor material, and two electrodes are connected with the p-semiconductor material and n-semiconductor material, respectively, wherein the p means positive type, n means negative type, i means intrinsic or semiconductor material within very low impurity. The semiconductor material may be monocrystalline silicon solar cells, polycrystalline silicon solar cells, amorphous silicon solar cells, cadmium telluride solar cells, CIS-based solar cells, CIGS-based solar cells, gallium arsenide solar cells, photochemical cells, dye-sensitized solar cells, polymer solar cells, nanocrystalline solar cells or their combinations. Similarly, such cell types are given by way of example and do not limit the present invention. Persons having ordinary skill in the art may flexibly choose the cell type of the solar cells 120 depending on actual requirements.

The solar panel 100 further includes a protective cover and a package layer, and the solar cells 120 and the bypass diodes 170a-170f are located between the substrate 110 and the protective cover, and secured by the package layer.

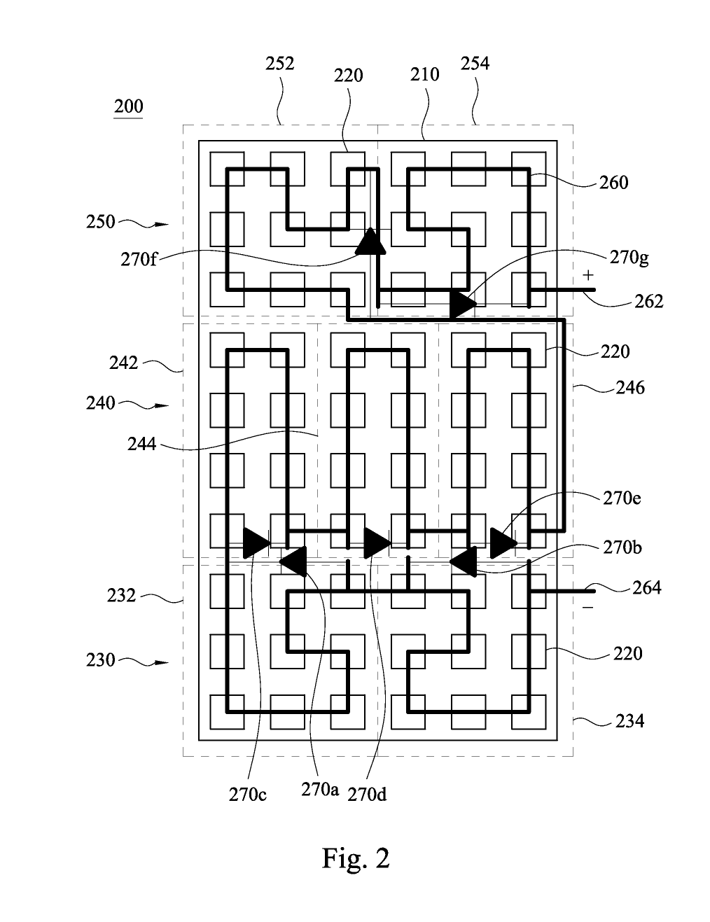

FIG. 2 is a schematic diagram of a solar panel according to a second embodiment of the present invention. The solar panel 200 includes a substrate 210 and a plurality of solar cells 220 disposed on the substrate 210. The solar cells 220 are disposed on the substrate 210 in rows and columns. According to the second embodiment of the present invention, the solar cells 220 are disposed on the substrate 210 in a 10×6 matrix. The solar cells 220 are formed in the shape of squares. In other embodiments, the solar cells 220 may be formed in the shape of rectangles, or circles, or other polygon shapes.

The substrate 210 includes a bottom area 230, a central area 240, and a top area 250 that are vertically and sequentially disposed from bottom to top. The bottom area 230 includes at least two rows of the solar cells 220, and the top area 250 includes at least two rows of the solar cells 220. The central area 240 is disposed between the bottom area 230 and the top area 250.

According to the second embodiment of the present invention, for example, the bottom area 230 includes three rows of the solar cells 220, the central area 240 includes four rows of the solar cells 220, and the top area 250 includes three rows of the solar cells 220. Each row includes six solar cells 220.

The bottom area 230 includes a fourth zone 232 and a fifth zone 234 that are horizontally and sequentially disposed from left to right. Each of the fourth zone 232 and the fifth zone 234 includes the solar cells 220 that are disposed in a 3×3 matrix.

The central area 240 has a first zone 242, a second zone 244, and a third zone 246 that are sequentially and horizontally disposed from left to right. Specifically, the first zone 242 is located at the left side of the central area 240, the third zone 246 is located at the right side of the central area 240, and the second zone 244 is located between the first zone 242 and the third zone 246. Each of the first zone 242, the second zone 244, and the third zone 246 includes the solar cells 220 that are disposed in a 4×2 matrix.

The top area 250 has a sixth zone 252 and a seventh zone 254 that are sequentially and horizontally disposed from left to right, and each of which includes the solar cells 220 that are disposed in a 3×3 matrix.

The solar panel 200 further includes a plurality of conducting wires 260, and the solar cells 220 are serially connected through the conducting wires 260. Wherein the conducting wires 260 is connected with the electrode of each of solar cell 220. The solar panel 200 includes a first terminal 262 and a second terminal 264 that have opposite polarities. According to the second embodiment of the present invention, the first terminal 262 is a positive electrode (or namely positive polarity end), and the second terminal 264 is a negative electrode (or namely negative polarity end). The first terminal 262 and the second terminal 264 are used to connect to external circuits or electrically connect to another solar panel. The first terminal 262 and the second terminal 264 are disposed on the same side of the substrate 210. Specifically, the first terminal 262 and the second terminal 264 of the conducting wires 260 are disposed on the same side of the substrate 210, and the first terminal 262 is connected to the rightmost and bottom row solar cell 220 in the top area 250, and the second terminal 264 is connected to the rightmost and top row solar cell 220 in the bottom area 230. The conducting wires 260 sequentially and serially connect the solar cells 220 in the seventh zone 254 of the top area 250 and the solar cells 220 in the sixth zone 252 of the top area 250, then sequentially and serially connect the solar cells 220 in the third zone 246 of the central area 240, the second zone 244 of the central area 240, and the first zone 242 of the central area 240, and finally sequentially and serially connect the solar cells 220 in the fourth zone 232 and the fifth zone 234 of the bottom area 230.

The solar panel 200 further includes a plurality of bypass diodes 270a-270g. The bypass diode 270a and the solar cells 220 of the fourth zone 232 are connected in parallel. The bypass diode 270b and the solar cells 220 of the fifth zone 234 are connected in parallel. The bypass diode 270c and the solar cells 220 of the first zone 242 are connected in parallel. The bypass diode 270d and the solar cells 220 of the second zone 244 are connected in parallel. The bypass diode 270e and the solar cells 220 of the third zone 246 are connected in parallel. The bypass diode 270f and the solar cells 220 of the sixth zone 252 are connected in parallel. The bypass diode 270g and the solar cells 220 of the seventh zone 254 are connected in parallel.

In other words, the solar panel 200 includes a first central area solar cell string in the first zone 242, a second central area solar cell string in the second zone 244, a third central area solar cell string in the third zone 246, a fourth bottom area solar cell string in the fourth zone 232, a fifth bottom area solar cell string in the fifth zone 234, a sixth top area solar cell string in the sixth zone 252, and a seventh top area solar cell string in the seventh zone 254. The first central area solar cell string, the second central area solar cell string, the third central area solar cell string, the fourth bottom area solar cell string, the fifth bottom area solar cell string, the sixth top area solar cell string, and the seventh top area solar cell string are connected in series.

The first central area solar cell string, the second central area solar cell string, and the third central area solar cell string are disposed between the fourth and fifth bottom area solar cell strings and the sixth and seventh top area solar cell strings. The second central area solar cell string is disposed between the first central area solar cell string and the third central area solar cell string. Each of the first central area solar cell string, the second central area solar cell string, the third central area solar cell string, the fourth bottom area solar cell string, the fifth bottom area solar cell string, the sixth top area solar cell string and the seventh top area solar cell string includes a plurality of the solar cells 220 connected in series to each other. Some of the solar cells 220 of the first central area solar cell string, the second central area solar cell string, the third central area solar cell string, the fourth bottom area solar cell string, the fifth bottom area solar cell string, the sixth top area solar cell string and the seventh top area solar cell string are connected to at least one bypass diode in parallel. If some of the solar cells 220 are shaded, then only the solar cell string of the solar cells 220 that are shaded will be bypassed, and other solar cells 220 that are not shaded will still normally function.

The substrate 210 may be made of glass, plastic or their combination. For instance, the substrate 210 may be made of tempered glass, polyvinyl fluoride (PVF, Tedlar® of DuPont), polyethylene terephthalate (PET), Polyethylene Naphthalate (PEN) or their combination. It is to be understood that such materials are given by way of example and do not limit the present invention. Persons having ordinary skill in the art may flexibly choose the materials of the substrate 210 depending on actual requirements.

The solar cells 220 has p-n semiconductor material or p-i-n semiconductor material, and two electrodes are connected with the p-semiconductor material and n-semiconductor material, respectively, wherein the p means positive type, n means negative type, i means intrinsic or semiconductor material within very low impurity. The semiconductor material may be monocrystalline silicon solar cells, polycrystalline silicon solar cells, amorphous silicon solar cells, cadmium telluride solar cells, CIS-based solar cells, CIGS-based solar cells, gallium arsenide solar cells, photochemical cells, dye-sensitized solar cells, polymer solar cells, nanocrystalline solar cells or their combinations. Similarly, such cell types are given by way of example and do not limit the present invention. Persons having ordinary skill in the art may flexibly choose the cell type of the solar cells 220 depending on actual requirements.

The solar panel 200 further includes a protective cover and a package layer, and the solar cell 220 and the bypass diodes 270a-270g are located between the substrate 210 and the protective cover, and secured by the package layer.

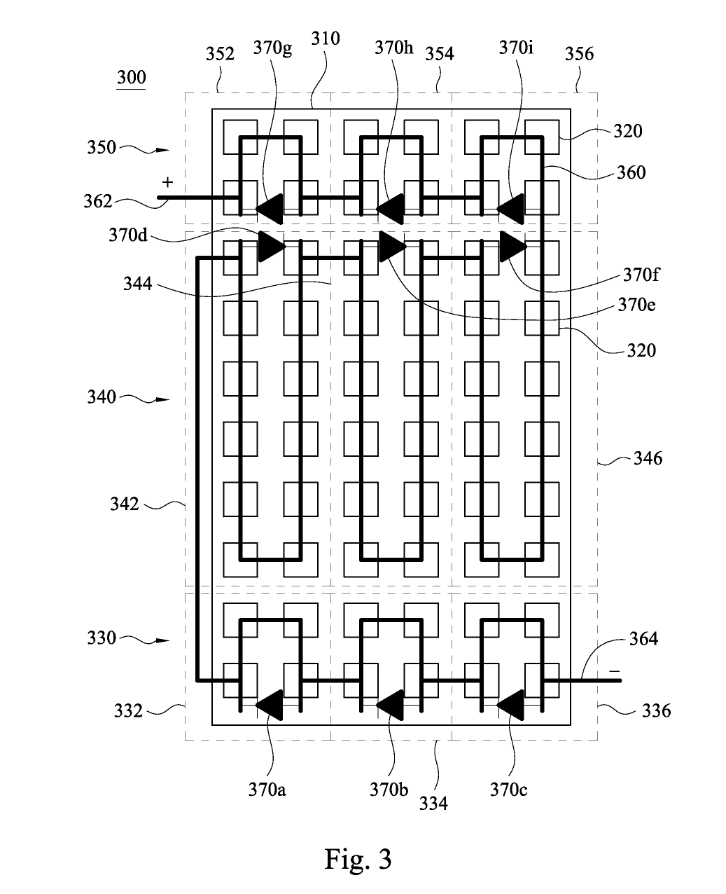

FIG. 3 is a schematic diagram of a solar panel according to a third embodiment of the present invention. The solar panel 300 includes a substrate 310 and a plurality of solar cells 320 disposed on the substrate 310. The solar cells 320 are disposed on the substrate 310 in rows and columns. According to the third embodiment of the present invention, the solar cells 320 are disposed on the substrate 310 in a 10×6 matrix. The solar cells 320 are formed in the shape of squares. In other embodiments, the solar cells 320 may be formed in the shape of rectangles, or circles, or other polygon shapes.

The substrate 310 includes a bottom area 330, a central area 340, and a top area 350 that are sequentially and vertically disposed from bottom to top. The bottom area 330 includes at least two rows of the solar cells 320, and the top area 350 includes at least two rows of the solar cells 320. The central area 340 is disposed between the bottom area 330 and the top area 350.

According to the third embodiment of the present invention, for example, the bottom area 330 includes two rows of the solar cells 320, the central area 340 includes six rows of the solar cells 320, and the top area 350 includes two rows of the solar cells 320. Each row includes six solar cells 320.

The bottom area 330 includes an eighth zone 332, a ninth zone 334 and a tenth zone 336 that are sequentially and horizontally disposed from left to right. The eighth zone 332 and the tenth zone 336 are located on opposite sides of the bottom area 330, and the ninth zone 334 is located between the eighth zone 332 and the tenth zone 336. Each of the eighth zone 332, the ninth zone 334 and the tenth zone 336 includes the solar cells 320 that are disposed in a 2×2 matrix.

The central area 340 has a first zone 342, a second zone 344, and a third zone 346 that are sequentially and horizontally disposed from left to right. Specifically, the first zone 342 is located at the left side of the central area 340, the third zone 346 is located at the right side of the central area 340, and the second zone 344 is located between the first zone 342 and the third zone 346. Each of the first zone 342, the second zone 344 and the third zone 346 includes the solar cells 320 that are disposed in a 6×2 matrix.

The top area 350 has an eleventh zone 352, a twelfth zone 354, and a thirteenth zone 356 that are sequentially and horizontally disposed from left to right. The eleventh zone 352 and the thirteenth zone 356 are located on opposite sides of the top area 350, and the twelfth zone 354 is located between the eleventh zone 352 and the thirteenth zone 356. Each of the eleventh zone 352, the twelfth zone 354, and the thirteenth zone 356 includes solar cells 320 disposed in a 2×2 matrix.

The solar panel 300 further includes a plurality of conducting wires 360, and the solar cells 320 are serially connected through the conducting wires 360. Wherein the conducting wires 360 is connected with the electrode of each of solar cell 320. The solar panel 300 includes a first terminal 362 and a second terminal 364 that have opposite polarities. According to the third embodiment, the first terminal 362 is a positive electrode (or namely positive polarity end), and the second terminal 364 is a negative electrode (or namely negative polarity end). The first terminal 362 and the second terminal 364 are used to connect to external circuits or electrically connect to another solar panel. The first terminal 362 and the second terminal 364 are disposed on different sides of the substrate 310. Specifically, the first terminal 362 and the second terminal 364 of the conducting wires 360 are disposed on opposite sides of the substrate 310. For instance, the first terminal 362 is connected to the leftmost solar cells 320 in the first row of the top area 350 (when the rows are counted from a bottom-to-top direction), and the second terminal 364 is connected to the rightmost solar cells 320 in the first row of the bottom area 330 (when the rows are counted from a bottom-to-top direction). The conducting wires 360 sequentially and serially connect the first terminal 362, the solar cells 320 of the eleventh zone 352, the twelfth zone 354, and the thirteenth zone 356 of the top area 350, then sequentially and serially connect the solar cells 320 in the third zone 346, the second zone 344, and the first zone 342 of the central area 340, and finally sequentially and serially connect the solar cells 320 of the eighth zone 332, the ninth zone 334, and the tenth zone 336 of the bottom area 330.

The solar panel 300 further includes a plurality of bypass diodes 370a-370i. The bypass diode 370a and the solar cells 320 of the eighth zone 332 are connected in parallel. The bypass diode 370b and the solar cells 320 of the ninth zone 334 are connected in parallel. The bypass diode 370c and the solar cells 320 of the tenth zone 336 are connected in parallel. The bypass diode 370d and the solar cells 320 of the first zone 342 are connected in parallel. The bypass diode 370e and the solar cells 320 of the second zone 344 are connected in parallel. The bypass diode 370f and the solar cells 320 of the third zone 346 are connected in parallel. The bypass diode 370g and the solar cells 320 of the eleventh zone 352 are connected in parallel. The bypass diode 370h and the solar cells 320 of the twelfth zone 354 are connected in parallel. The bypass diode 370i and the solar cells 320 of the thirteenth zone 356 are connected in parallel.

In other words, the solar panel 300 includes a first central area solar cell string in the first zone 342, a second central area solar cell string in the first zone 344, a third central area solar cell string in the third zone 346, an eighth bottom area solar cell string in the eighth area 332, a ninth bottom area solar cell string in the ninth zone 334, a tenth bottom area solar cell string in the tenth zone 336, an eleventh top area solar cell string in the eleventh zone 352, a twelfth top area solar cell string in the twelfth zone 354, and a thirteen top area solar cell string in the thirteenth zone 356. The first central area solar cell string, the second central area solar cell string, the third central area solar cell string, the eighth bottom area solar cell string, the ninth bottom area solar cell string, the tenth bottom area solar cell string, the eleventh top area solar cell string, the twelfth top area solar cell string, and a thirteen top area solar cell string are connected in series.

The first central area solar cell string, the second central area solar cell string, and the third central area solar cell string are disposed between the eighth through tenth bottom area solar cell strings and the eleventh through thirteenth top area solar cell strings. The second central area solar cell string is disposed between the first central area solar cell string and the third central area solar cell string. Each of the first central area solar cell string, the second central area solar cell string, the third central area solar cell string, the eighth bottom area solar cell string, the ninth bottom area solar cell string, the tenth bottom area solar cell string, the eleventh top area solar cell string, the twelfth top area solar cell string and the thirteenth top area solar cell string includes a plurality of the solar cells 320 connected in series to each other. Some of the solar cells 320 of the first central area solar cell string, the second central area solar cell string, the third central area solar cell string, the eighth bottom area solar cell string, the ninth bottom area solar cell string, the tenth bottom area solar cell string, the eleventh top area solar cell string, the twelfth top area solar cell string and the thirteenth top area solar cell string are connected to at least one bypass diode in parallel. If some of the solar cells 320 are shaded, then only the solar cell string of the solar cells 320 that are shaded will be bypassed, and other solar cells 320 that are not shaded will still normally function.

The substrate 310 may be made of glass, plastic or their combination. For instance, the substrate 310 may be made of tempered glass, polyvinyl fluoride (PVF, Tedlar® of DuPont), polyethylene terephthalate (PET), Polyethylene Naphthalate (PEN) or their combination. It is to be understood that such materials of the substrate 310 are given by way of example and do not limit the present invention. Person having ordinary skill in the art may flexibly choose the material of the substrate 310 depending on actual requirements.

The solar cells 320 has p-n semiconductor material or p-i-n semiconductor material, and two electrodes are connected with the p-semiconductor material and n-semiconductor material, respectively, wherein the p means positive type, n means negative type, i means intrinsic or semiconductor material within very low impurity. The semiconductor material may be monocrystalline silicon solar cells, polycrystalline silicon solar cells, amorphous silicon solar cells, cadmium telluride solar cells, CIS-based solar cells, CIGS-based solar cells, gallium arsenide solar cells, photochemical cells, dye-sensitized solar cells, polymer solar cells, nanocrystalline solar cells or their combinations. Similarly, such cell types are given by way of example and do not limit the present invention. Persons having ordinary skill in the art may flexibly choose the cell type of the solar cells 320 depending on actual requirements.

The solar panel 300 further includes a protective cover and a package layer, and the solar cell 320 and the bypass diodes 370a-370i are located between the substrate 310 and the protective cover, and secured by the package layer.

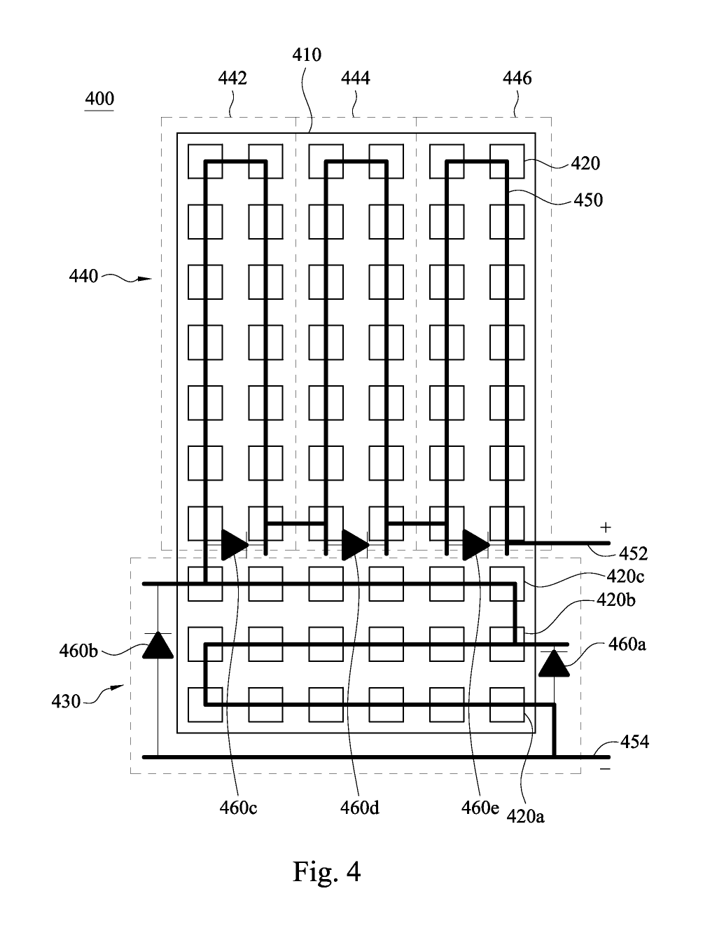

FIG. 4 is a schematic diagram of a solar panel according to a fourth embodiment of the present invention. The solar panel 400 includes a substrate 410 and a plurality of solar cells 420 disposed on the substrate 410. The solar cells 420 are disposed on the substrate 410 in rows and columns. According to the fourth embodiment of the present invention, the solar cells 420 are disposed on the substrate 410 in a 10×6 matrix. The solar cells 420 are formed in the shape of squares. In other embodiments, the solar cells 420 may be formed in the shape of rectangles, or circles, or other polygon shapes.

The substrate 410 includes a bottom area 430 and a top area 440 that are sequentially and vertically disposed from bottom to top. The bottom area 430 includes at least two rows of the solar cells 420. According to the fourth embodiment, for example, the bottom area 430 includes three rows of the solar cells 320, and the top area 440 includes seven rows of the solar cells 420. Each row includes six solar cells 420.

The top area 440 has a first zone 442, a second zone 444, and a third zone 446 that are sequentially and horizontally disposed from left to right. Specifically, the first zone 442 is located at the left side of the top area 440, the third zone 446 is located at the right side of the top area 440, and the second zone 444 is located between the first zone 442 and the third zone 446.

The solar panel 400 further includes a plurality of conducting wires 450, and the solar cells 420 are serially connected through the conducting wires 450. Wherein the conducting wires 450 is connected with the electrode of each of solar cell 420. The solar panel 400 includes a first terminal 452 and a second terminal 454 that have opposite polarities. According to the fourth embodiment of the present invention, the first terminal 452 is a positive electrode (or namely positive polarity end) and the second terminal 454 is a negative electrode (or namely negative polarity end). The first terminal 452 and the second terminal 454 are used to connect to external circuits or electrically connect to another solar panel. The first terminal 452 and the second terminal 454 are disposed on the same side of the substrate 410. Specifically, the first terminal 452 and the second terminal 454 of the conducting wires 450 are disposed on the same side of the substrate 410, and the first terminal 452 is connected to the rightmost solar cell 420 in the last row of the top area 440, and the second terminal 454 is connected to the rightmost solar cell 420 in the last row of the bottom area 430. The conducting wires 450 sequentially and serially connect the first terminal 452, the solar cells 420 of the third zone 446, the second zone 444, and the first zone 442 of the top area 440, then sequentially and serially connect the solar cells 420 of the bottom area 430.

The solar panel 400 further includes a plurality of bypass diodes 460a-460e. The bypass diodes 460a and 460b are connected in parallel with the solar cells 420 of the bottom area 430. Specifically, the bottom area 430 includes a first row of solar cells 420a, a second row of solar cells 420b, and a third row of solar cells 420c that are vertically and sequentially connected from bottom to top. The bypass diode 460a is connected to the first row of solar cells 420a and the second row of solar cells 420b, and the bypass diode 460b is connected to the first row of solar cells 420a and the third row of solar cells 420c. The bottom area 430 includes the bypass diodes 460a and 460b to prevent the generation of hot spots occurring due to partial shading of the solar panel 100. The bypass diode 460c is connected with the solar cells 420 of the first zone 442 of the top area 440, the bypass diode 460d is connected with the solar cells 420 of the second zone 444 of the top area 440, and the bypass diode 460e is connected with the solar cells 420 of the third zone 446 of the top area 440. The bypass diodes 460c-460e of the top area 440 are connected to two adjacent rows of the solar cells 420, respectively, preferred, the bypass diodes 460c-460e of the top area 440 are connected to two immediately adjacent rows of the solar cells 420. It is to be noted that in practice, the bypass diodes 460a-460e are all disposed on the substrate 410. However, in FIG. 4, the bypass diodes 460a and 460b are shown positioned outside of the substrate 410 so as to enable clear depiction of the connections thereof with elements of the solar panel 400.

In other words, the solar panel 400 includes a bottom area solar cell string in the bottom area 430, a first top area solar cell string in the first zone 442, a second top area solar cell string in the second zone 444, and a third top area solar cell string in the third zone 446. The bottom area solar cell string, the first top area solar cell string, the second top area solar cell string, and the third top area solar cell string are connected in series. The second top area solar cell string is located between the first top area solar cell string and the third top area solar cell string. Each of the bottom area solar cell string, the first top area solar cell string and the third top area solar cell string includes a plurality of solar cells 420 connected to each other. Some of the solar cells 420 of the bottom area solar cell string, the first top area solar cell string and the third top area solar cell string are connected to at least one bypass diode in parallel. If some of the solar cells 420 are shaded, then only the solar cell string of the solar cells 420 that are shaded will be bypassed, and other solar cells 420 that are not shaded will still normally function.

The substrate 410 may be made of glass, plastic or their combination. For instance, the substrate 110 may be made of tempered glass, polyvinyl fluoride (PVF, Tedlar® of DuPont), polyethylene terephthalate (PET), Polyethylene Naphthalate (PEN) or their combination. It is to be understood that such materials are given by way of example and do not limit the present invention. Persons having ordinary skill in the art may flexibly choose the materials of the substrate 410 depending on actual requirements.

The solar cells 420 has p-n semiconductor material or p-i-n semiconductor material, and two electrodes are connected with the p-semiconductor material and n-semiconductor material, respectively, wherein the p means positive type, n means negative type, i means intrinsic or semiconductor material within very low impurity. The semiconductor material may be monocrystalline silicon solar cells, polycrystalline silicon solar cells, amorphous silicon solar cells, cadmium telluride solar cells, CIS-based solar cells, CIGS-based solar cells, gallium arsenide solar cells, photochemical cells, dye-sensitized solar cells, polymer solar cells, nanocrystalline solar cells or their combinations. Similarly, such cell types are given by way of example and do not limit the present invention. Persons having ordinary skill in the art may flexibly choose the cell type of the solar cells 420 depending on actual requirements.

The solar panel 400 further includes a protective cover and a package layer, and the solar cells 420 and the bypass diodes 460a-460e are located between the substrate 410 and the protective cover, and secured by the package layer.

It is to be noted that although the aforementioned embodiment describes the solar cells in a 10×6 matrix, in practice, the aforementioned embodiment can also be applied to the solar cells in a 12×6 matrix if the proper modification is made to the solar cells of the first zone, the second zone and the third zone.

The solar panel of the present invention includes different areas of solar cells. Bypass diodes are implemented in each area of solar cells, and depending on environmental conditions, are used to realize a suitable solar panel configuration to keep power generation loss to a minimum due to partial shading on the solar panel.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar panel comprising:
a substrate having a bottom area, a central area, and a top area that are sequentially and vertically disposed from bottom to top, wherein the central area comprises a first zone, a second zone, and a third zone that are sequentially and horizontally disposed from left to right;
a plurality of solar cells disposed on the substrate in rows and columns, wherein the bottom area comprises at least two rows of the solar cells, and the top area comprises at least two rows of the solar cells;
a plurality of conducting wires sequentially connected with the solar cells in series; and
a plurality of bypass diodes disposed on the substrate, wherein each of the bottom area, the central area, the top area, the first zone, the second zone, and the third zone comprises at least one of the bypass diodes.

2. The solar panel of claim 1, wherein the solar cells are disposed on the substrate in a 10×6 matrix.

3. The solar panel of claim 1, wherein the solar cells are disposed on the substrate in a 12×6 matrix.

4. The solar panel of claim 1, wherein the bottom area comprises a first row of solar cells, a second row of solar cells, and a third row of solar cells that are sequentially and vertically connected from bottom to top, and the bypass diodes are disposed on the bottom area, wherein one of the bypass diodes is connected between the first row of the solar cells and the second row of the solar cells, and another one of the bypass diodes is connected between the first row of the solar cells and the third row of the solar cells.

5. The solar panel of claim 4, wherein each of the bypass diodes of the central area and the top area is connected between the solar cells of two adjacent rows or adjacent columns.

6. The solar panel of claim 1, wherein the bottom area comprises a fourth zone and a fifth zone that are sequentially and horizontally disposed from left to right, and each of the fourth zone and the fifth zone comprises a bypass diode.

7. The solar panel of claim 6, wherein the top area comprises a sixth zone and a seventh zone that are sequentially and horizontally disposed from left to right, and each of the sixth zone and the seventh zone comprises a bypass diode.

8. The solar panel of claim 7, wherein the bottom area comprises an eighth zone, a ninth zone, and a tenth zone that are sequentially and horizontally disposed from left to right, and each of the eighth zone, the ninth zone, and the tenth zone comprises a bypass diode.

9. The solar panel of claim 8, wherein the top area comprises an eleventh zone, a twelfth zone, and a thirteenth zone that are sequentially and horizontally disposed from left to right, and each of the eleventh zone, the twelfth zone, and the thirteenth zone comprises a bypass diode.

10. The solar panel of claim 1, further comprising two terminals that have opposite polarities, are disposed on the same side of the substrate, and are electrically connected to external circuits or another solar panel.

11. The solar panel of claim 1, further comprising two terminals that have opposite polarities, are disposed on opposite sides of the substrate, and are electrically connected to external circuits or another solar panel.

12. A solar panel comprising:
a substrate having a bottom area and a top area that are sequentially and vertically disposed from bottom to top, wherein the top area has a first zone, a second zone, and a third zone that are sequentially and horizontally disposed from left to right;
a plurality of solar cells disposed on the substrate in rows and columns, wherein the bottom area comprises at least two rows of the solar cells;
a plurality of conducting wires sequentially connected with the solar cells in series; and
a plurality of bypass diodes disposed on the substrate, wherein each of the first zone, the second zone, and the third zone comprises at least one bypass diode, and the bottom area comprises at least one bypass diode.

13. The solar panel of claim 12, wherein the bottom area comprises the first row, the second row, and the third row of the solar cells and two bypass diodes, wherein one of the bypass diodes is connected between the first row of the solar cells and the second row of the solar cells, and the other one of the bypass diodes is connected between the first row of the solar cells and the third row of the solar cells.

14. The solar panel of claim 13, wherein each of the bypass diodes of the top area is connected between two adjacent rows of the solar cells.

15. The solar panel of claim 12, further comprising two terminals that have opposite polarities, are disposed on opposite sides of the substrate, and are electrically connected to external circuits or another solar panel.
